(19) United States
(12) Patent Application Publication
(10) Pub. No.: US 2013/0127069 A1
(43) Pub. Date: May 23, 2013

(54) MATRICES FOR RAPID ALIGNMENT OF GRAPHITIC STRUCTURES FOR STACKED CHIP COOLING APPLICATIONS

(71) Applicants: Dylan J. BODAY, Tucson, AZ (US); Joseph KUCZYNSKI, Rochester, MN (US); Robert E. MEYER, III, Rochester, MN (US)

(72) Inventors: Dylan J. BODAY, Tucson, AZ (US); Joseph KUCZYNSKI, Rochester, MN (US); Robert E. MEYER, III, Rochester, MN (US)

(73) Assignee: INTERNATIONAL BUSINESS MACHINES CORPORATION, Armonk, NY (US)

(21) Appl. No.: 13/298,438

(22) Filed: Nov. 17, 2011

(51) Int. Cl. H01L 23/34; B32B 5/08; B32B 7/02; B28B 1/093; B29C 35/08; B82Y 30/00

(52) U.S. Cl. 257/777; 425/3; 264/429; 428/98; 428/119; 428/212; 977/762; 257/E23.08

(57) ABSTRACT

The chip stack of semiconductor chips with enhanced cooling apparatus includes a first chip and a second chip electrically and mechanically coupled by a grid of connectors. The chip stack includes a thermal interface material (TIM) between the first chip and the second chip. The TIM includes nanofibers aligned parallel to mating surfaces of the first and second chips, and a thermosetting polymer that when heated, will reduce the viscosity of the TIM to allow for optimal alignment of the carbon nanofibers. The method includes adding at least one thermosetting polymer to the TIM, dispersing nanofibers into the TIM, and heating the TIM until the thermosetting polymer un-crosslinks. The method further includes applying a magnetic field to align the graphite nanofibers and cooling the TIM until the thermosetting polymer re-crosslinks.

### FIELD OF THE INVENTION

The present invention generally relates to thermal interface materials, and more particularly, to matrices for rapid alignment of nanofibers containing a magnetic material for stacked chip cooling applications.

### BACKGROUND

Thermal interfaces in microelectronics packages are commonly credited with a majority of the resistance for heat to escape from the chip to an attached cooling device (e.g. heat sinks, spreaders and the like). Thus, in order to minimize the thermal resistance between the heat source and cooling device, a thermally conductive paste, thermal grease or adhesive is commonly used. Thermal interfaces are typically formed by pressing the heat sink or chip cap onto the backside of the processor chip with a particle filled viscous medium between, which is forced to flow into cavities or non-uniformities between the surfaces.

Thermal interface materials are typically composed of an organic matrix highly loaded with a thermally conductive filler. Thermal conductivity is driven primarily by the nature of the filler, which is randomly and homogeneously distributed throughout the organic matrix. Commonly used fillers exhibit isotropic thermal conductivity and thermal interface materials utilizing these fillers must be highly loaded to achieve the desired thermal conductivity. Unfortunately, these loading levels degrade the properties of the base matrix material (such as flow, cohesion, interfacial adhesion, etc.).

It has been determined that stacking layers of electronic circuitry (i.e. 3 dimensional chip stack) and vertically interconnecting the layers provides a significant increase in circuit density per unit area. However, one significant problem of the three dimensional chip stack is heat dissipation from the inner chips. For a four layer 3 dimensional chip stack, the surface area presented to the heat sink by the chip stack has only ¼ of the surface area presented by the two-dimensional approach. For a 4-layer chip stack, there are three layer-layer thermal interfaces in addition to the final layer to grease/heat sink interface. The heat from the bottom layers must be conducted up thru the higher layers to get to the grease/heat sink interface.

One approach utilizes nanotubes, such as for example carbon nanotubes (CNTs), to promote heat dissipation from the inner chips. However, the CNTs are randomly oriented in the thermal interface material (TIM). CNTs and other thermally conductive carbon structures exhibit anisotropic thermal conductivity such that the thermal conductivity is orders of magnitude greater along one axis. Random distribution of the CNTs does not maximize the thermal conductivity of the TIM. Recently, another approach has been disclosed for the alignment of carbon structures which allows for 3D chip stacks to have aligned CNTs or any form of carbon nanofibers (CNF), such as for example graphite nanofibers (GNFs), in the xy plane, such that heat may be brought to the edges of the stack. However, the viscosity of the TIM makes alignment difficult.

### BRIEF SUMMARY

The exemplary embodiments of the present invention provide a method for enhancing internal layer-layer thermal interface performance and a device made from the method. In particular, disclosed is a method and system for aligning carbon nanofibers containing a magnetic material in a thermal interface material used in three dimensional chip stacks.

An exemplary embodiment includes a method for aligning a plurality of nanofibers containing a magnetic material in a thermal interface material to enhance the thermal interface material performance. The method includes adding at least one thermosetting polymer to the thermal interface material, dispersing the plurality of nanofibers containing a magnetic material into the thermal interface material, and heating the thermal interface material until the thermosetting polymer un-crosslinks. The method further includes applying a magnetic field of sufficient intensity to align the nanofibers containing a magnetic material in the thermal interface material and cooling the thermal interface material until the thermosetting polymer re-crosslinks.

Another exemplary embodiment includes a chip stack of semiconductor chips with enhanced cooling apparatus. Briefly described in terms of architecture, one embodiment of the apparatus, among others, is implemented as follows. The chip stack of semiconductor chips with enhanced cooling apparatus includes a first chip with circuitry on a first side and a second chip electrically and mechanically coupled to the first chip by a grid of connectors. The chip stack further includes a thermal interface material pad between the first chip and the second chip. The thermal interface material pad comprises a plurality of nanofibers containing a magnetic material, aligned parallel to mating surfaces of the first chip and the second chip, and a thermosetting polymer that when heated to approximately 110° C., the thermosetting polymer will un-crosslink and reduce the viscosity of the thermal interface material to allow for optimal alignment of the nanofibers containing a magnetic material.

Another exemplary embodiment includes a system for aligning a plurality of nanofibers containing a magnetic material in a thermal interface material to enhance the thermal interface material performance. Briefly described in terms of architecture, one embodiment of the system, among others, is implemented as follows. The system includes a means for adding at least one thermosetting polymer to the thermal interface material, a means for dispersing the plurality of nanofibers containing a magnetic material into the thermal interface material, and a means for heating the thermal interface material until the thermosetting polymer un-crosslinks. The system further includes a means for applying a magnetic field of sufficient intensity to align the nanofibers containing a magnetic material in the thermal interface material, and a means for cooling the thermal interface material until the thermosetting polymer re-crosslinks.

Another exemplary embodiment includes an apparatus comprising a first object, a second object and a thermal interface material. The thermal interface material includes having a thickness between a first surface of the thermal interface material and a second surface of the thermal interface material. The thermal interface material further includes a plurality of nanofibers aligned parallel to the first surface and the second surface, and at least one thermosetting polymer that when heated to at least 110° C., the at least one thermosetting polymer will un-crosslink and reduce the viscosity of the thermal interface material to allow for optimal alignment of the plurality of nanofibers.

These and other aspects, features and advantages of the invention will be understood with reference to the drawing figures and detailed description herein, and will be realized by means of the various elements and combinations particularly pointed out in the appended claims. It is to be understood that both the foregoing general description and the following brief description of the drawing and detailed description of the invention are exemplary and explanatory of preferred embodiments of the invention, and are not restrictive of the invention, as claimed.

### BRIEF DESCRIPTION OF THE SEVERAL VIEWS OF THE DRAWINGS

The subject matter, which is regarded as the invention, is particularly pointed out and distinctly claimed in the claims at the conclusion of the specification. The foregoing and other objects, features, and advantages of the invention are apparent from the following detailed description taken in conjunction with the accompanying drawings in which:

FIG. 1 is a cross section block diagram illustrating an example of the C4 or flip chip connection channels in a silicon device stack utilizing the thermal interface material with nanofibers containing a magnetic material aligned along the conductive axis in the desired direction of the present invention.

FIG. 2A is a block diagram illustrating an example of the nanofibers containing a magnetic material randomly dispersed in the thermal interface material.

FIG. 2B is a block diagram illustrating an example of the thermal interface material with nanofibers containing a magnetic material brought to an elevated temperature, leading to an uncross-linking reaction of the thermal interface material in an oven then aligned to orient the conductive axis in the desired direction in the thermal interface material.

FIG. 2C is a graph illustrating an example of the thermal interface material viscosity reduction by an uncross-linking reaction of the thermal interface material as compared to typical PCMs.

FIG. 2D is a block diagram illustrating an example of the slicing the thermal interface material into the desired footprint.

FIG. 3A and 3B are block diagrams illustrating an example of the thermal interface material with nanofibers containing a magnetic material brought to an elevated temperature, leading to an uncross-linking reaction of the thermal interface material in an oven, then aligned to orient the conductive axis of the nanofibers containing a magnetic material in perpendicular directions to the thermal interface material, and having a plurality of punch holes formed at various locations thereon.

FIG. 4 is a block diagram illustrating an example of the thermal interface material with nanofibers containing a magnetic material arranged such that two opposite sides of the thermal interface material with nanofibers are aligned to conduct heat in the east/west direction and another two opposite sides conduct heat in the north/south direction.

FIG. 5 is a block diagram illustrating another example of the thermal interface material with nanofibers containing a magnetic material arranged such that two opposite sides of the thermal interface material with nanofibers containing a magnetic material are aligned to conduct heat in the east/west direction and another two opposite sides conduct heat in the north/south direction.

FIG. 6 is a flow chart illustrating an example of a method of forming a silicon device utilizing the thermal interface material with nanofibers containing a magnetic material heated and aligned to orient the conductive axis in the desired direction of the present invention.

FIG. 7 is a flow chart illustrating an example of a method of forming a silicon device utilizing the thermal interface material with nanofibers containing a magnetic material heated and aligned by using a solvent to orient the conductive axis in the desired direction of the present invention.

The detailed description explains the preferred embodiments of the invention, together with advantages and features, by way of example with reference to the drawings.

### DETAILED DESCRIPTION

The present invention may be understood more readily by reference to the following detailed description of the invention taken in connection with the accompanying drawing figures, which form a part of this disclosure. It is to be understood that this invention is not limited to the specific devices, methods, conditions or parameters described and/or shown herein, and that the terminology used herein is for the purpose of describing particular embodiments by way of example only and is not intended to be limiting of the claimed invention.

One or more exemplary embodiments of the invention are described below in detail. The disclosed embodiments are intended to be illustrative only since numerous modifications and variations therein will be apparent to those of ordinary skill in the art.

One or more exemplary embodiments of the invention disclose a thermal interface material formulation, which allows for nanofibers containing a magnetic material to be aligned once a trigger renders a gel like thermal interface material (TIM) into a lower viscosity material allowing for a more facile method of alignment. Once alignment is accomplished, the thermal interface material converts back to a solid gel. This can be accomplished via the use of reversible Diels-Alder chemistry and reversible phenol and isocyanate chemistry.

One or more exemplary embodiments of the invention are directed to providing a thermal interface material that is placed between chips in a chip stack. The thermal interface material having nanofibers/nanotubes, containing a magnetic material, aligned to efficiently transfer heat to at least two sides (e.g., east and west, or north and south) of a chip stack. The thermal interface material base is created by mixing at least one polymer for a thermal interface material base. The nanofibers/nanotubes containing a magnetic material are mixed into the thermal interface material and are allowed to cure. The thermal interface material is then treated to un-crosslink the least one polymer in the thermal interface material. In the preferred embodiment, heat is applied to un-crosslink the least one polymer in the thermal interface material. In an alternative embodiment, a solvent or reactive chemical is applied to the thermal interface material to un-crosslink the least one polymer in the thermal interface material. In still another alternative embodiment, a disulfide crosslinked epoxy can be used. The disulfide bond can be reduced using phosphines and then oxidized to reform the disulfide bond. Each example embodiment renders the gel like TIM material into a lower viscosity material allowing for a more facile method of alignment. Next, the nanofibers/nanotubes containing a magnetic material are aligned within the lower viscosity thermal interface material. In the preferred embodiment, a magnetic field is applied in a direction parallel to sides of a pad that would be in contact with semiconductor chips or other like electronic devices. The field is strong enough to align the nanofibers/nanotubes containing a magnetic material. The material is then cooled, sliced into pads and placed between layers of chips in the chip stack.

In one embodiment, all nanofibers/nanotubes containing a magnetic material are aligned “east/west” and draw the heat to heat sinks (i.e. heat dissipating objects) on the east and west sides of the chip stack. In another embodiment, the pads are alternated among chips so that alternating layers draw heat to heat sinks on the east/west sides of the chip stack and to the north/south side of the chip stack. In still another embodiment, pieces of the pads are arranged such that two opposite sides of the arrangement conduct heat east/west and another two opposite sides conduct heat north/south. In this embodiment, the nanofibers/nanotubes containing a magnetic material are arranged so that both ends are perpendicular to the closest edge of the pad.

A thermal interface material is used to fill the gaps between thermal transfer surfaces, such as between microprocessors and heat sinks, in order to increase thermal transfer efficiency. These gaps are normally filled with air, which is a very poor conductor. A thermal interface material may take on many forms. The most common is the white-colored paste or thermal grease, typically silicone oil filled with aluminum oxide, zinc oxide, or boron nitride. Some brands of thermal interface materials use micronized or pulverized silver. Another type of thermal interface materials are the phase-change materials. The phase change materials are solid at room temperature, but liquefy and behave like grease at operating temperatures.

A phase change material is a substance with a high heat of fusion which, melting and solidifying at a certain temperature, is capable of storing and releasing large amounts of energy. Heat is absorbed or released when the material changes from solid to liquid and vice versa; thus, phase change materials are classified as latent heat storage units.

Phase change materials latent heat storage, can be achieved through solid-solid, solid-liquid, solid-gas and liquid-gas phase change. However, the only phase change used for thermal interface materials is the solid-liquid change. Liquid-gas phase changes are not practical for use as thermal storage due to the large volumes or high pressures required to store the materials when in their gas phase. Liquid-gas transitions do have a higher heat of transformation than solid-liquid transitions. Solid-solid phase changes are typically very slow and have a rather low heat of transformation.

Initially, the solid-liquid phase change materials behave like sensible heat storage materials; their temperature rises as they absorb heat. Unlike conventional sensible heat storage, however, when phase change materials reach the temperature at which they change phase (i.e. melting temperature) they absorb large amounts of heat at an almost constant temperature. The phase change material continues to absorb heat without a significant rise in temperature until all the material is transformed to the liquid phase. When the ambient temperature around a liquid material falls, the phase change material solidifies, releasing its stored latent heat. A large number of phase change materials are available in any required temperature range from −5 up to 190° C. Within the human comfort range of 20° to 30° C., some phase change materials are very effective. They can store 5 to 14 times more heat per unit volume than conventional storage materials such as water, masonry, or rock.

It is well known that the incorporation of certain types of carbon nanofibers into thermal interface material can impart thermal conductivity to such materials. Carbon nanofibers or carbon nanotubes, can be dispersed in thermal interface material by various well-known techniques. These techniques include, but are not limited to, melting, kneading and dispersive mixers to form an admixture that can be subsequently shaped to form a thermally conductive article.

Nanofibers are defined as fibers with diameters on the order of 100 nanometers. They can be produced by interfacial polymerization and electrospinning. In one embodiment, carbon nanofibers are graphitized fibers produced by catalytic synthesis around a catalytic core. The catalytic core around which graphite platelets are formed is, for exemplary purposes, called a metal seed or a catalytic metal seed, wherein the catalytic metal seed is a material having magnetic properties such as iron, cobalt, or nickel. Other non-metal materials suitable for forming magnetically alignable carbon nanofibers are within the scope of the invention.

Carbon nanofibers can be grown in numerous shapes around a catalytic seed. From the physical point of view, carbon nanofibers vary from 5 to 100 microns in length and are between 5 to 100 nm in diameter. In one embodiment, the carbon nanofibers comprised of graphite platelets are arranged in various orientations with respect to the long axis of the fiber, giving rise to assorted conformations. In another embodiment, a magnetic field is applied to the metal catalyst prior to deposition of the carbon nanofibers on the metal-core. With the application of a magnetic field, the magnetic poles of the seed are aligned with the magnetic field and will subsequently carry the attached carbon nanofibers along with them as they rotate in the applied field following deposition.

Carbon nanotubes (CNTs) are allotropes of carbon with a cylindrical nanostructure. Nanotubes have been constructed with a length-to-diameter ratio of up to 132,000,000:1, significantly larger than any other material. They exhibit extraordinary strength and unique electrical properties, and are efficient thermal conductors. Nanotubes are members of the fullerene structural family, which also includes the spherical buckyballs. The ends of a nanotube may be capped with a hemisphere of the buckyball structure. Their name is derived from their size, since the diameter of a nanotube is on the order of a few nanometers (approximately 1/50,000th of the width of a human hair), while they can be up to 18 centimeters in length.

Carbon nanofibers and nanotubes have received considerable attention in the electronics field due to their remarkable thermal conductivity. Moreover, the thermal conductivity of carbon nanofibers and nanotubes are anisotropic. Anisotropy is the property of being directionally dependent, as opposed to isotropy, which implies homogeneity in all directions. Therefore, the present invention takes advantage of the anisotropic nature of the carbon nanofibers and nanotubes by effectively aligning them along the conductive axis, thereby generating a thermal interface material with exceptional thermal conductivity at comparatively low loading levels. Diamond, graphite, and graphite fibers have been known as excellent heat conductors with a high thermal conductivity up to 3000 W/m-K.

Currently in known thermal interface materials, the polymeric matrix when the alignment would occur is very viscous. This makes alignment difficult. In one embodiment of the present invention is a TIM formulation that allows for carbon fiber like structures to be aligned once a thermal trigger is reached which renders the gel like TIM material into a lower viscosity material. This allows for a more facile method of alignment. Once alignment is accomplished, the temperature is reduced and the TIM converts back to a solid gel. This can be accomplished via the use of reversible Diels-Alder chemistry, reversible phenol and isocyanate chemistry or the like.

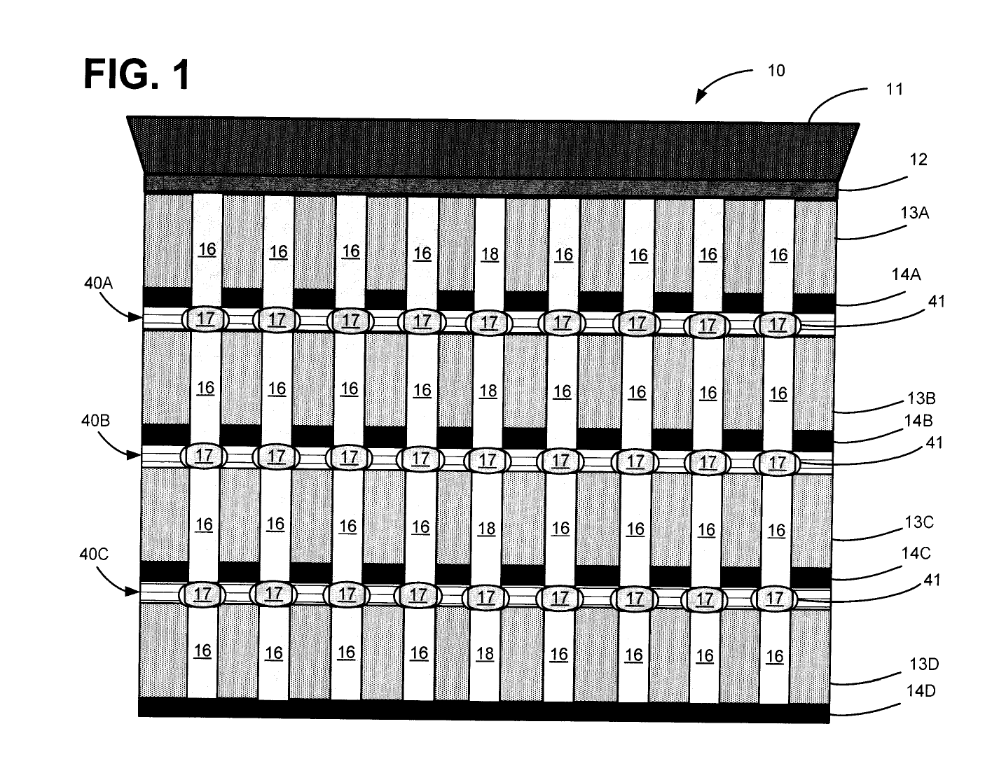

Referring now to the drawings, in which like numerals illustrate like elements throughout the several views. FIG. 1 is a cross section block diagram illustrating an example of a controlled collapse chip connection 17 (i.e. C4) or flip chip electrically conductive channels 16 and thermal conductive channels 18 utilized in a chip stack 10.

The chip stack 10 comprises a multitude of chips 13 (A-D) that further include one or more electrically conductive channels 16 and/or thermal conductive channels 18, which extend through a chip 13 from the top surface to the bottom surface. In one embodiment, the “conductive channel” is really a combination of two or more thru-silicon-vias (TSVs) connected sequentially by one or more controlled collapse chip connection 17 (C4s).

Preferably, the electrically conductive channels 16 are formed of tungsten or copper; however, other conductive materials may be used and are contemplated. The electrically conductive channels 16 selectively conduct electrical signals to and from portions of the circuitry 14 thereon or simply couple to solder bumps 17 to interconnect differing chips 13 in the chip stack 10 (e.g., chips 13A and 13B), or both. The solder bumps 17 are located within an area 41 of a thermal interface material (TIM) pad 40. In one embodiment, the area 41 is punched out of the TIM pad 40. In another embodiment, the area 41 is formed during the creation of the TIM pad 40.

The TIM pad 40 comprises carbon nanotubes (CNTs), carbon nanofibers (CNF), graphic nanofibers (GNFs) or the like, that are dispersed in a phase change material (PCM) or a silicone grease. After the PCM viscosity has been lowered either through heat or a solvent, the CNTs, CNFs or GNFs are then aligned in the xy plane (i.e. positioned parallel to the surface of the chip 13). This is so that heat may be brought to the edges of the chip stack 10. Once the heat is brought to the edges of the chip stack 10, multiple heat sinks or other type devices may be utilized to more efficiently dissipate that heat of the chip stack 10.

In one embodiment, CNTs, CNFs or GNFs are aligned in the thermal interface material 30 in one direction by an applied magnetic field. By aligning the CNTs, CNFs or GNFs along the conductive axis in the xy plane of the 3D chip stack 10 creates a TIM pad 40 with exceptional thermal conductivity at comparatively low loading levels. The system and method for aligning graphic nanofibers to enhance thermal interface material performance are described in commonly assigned and co-pending U.S. Patent Application (Attorney Docket ROC920100010US1) entitled “A METHOD AND SYSTEM FOR ALIGNMENT OF CARBON NANOFIBERS FOR ENHANCED THERMAL INTERFACE MATERIAL PERFORMANCE”, Ser. No. 12/842,200 filed on, Jul. 23, 2010, and U.S. Patent Application (Attorney Docket ROC9201100670US1) entitled “A System and Method to Process Horizontally Aligned Graphite Nanofibers in a Thermal Interface Material Used in 3D Chip Stacks”, Ser. No. 13/188,572 filed on, Jul. 22, 2011, both herein incorporated by reference.

Preferably, the thermal conductive channels 18 are formed and filled with conductive materials, metal or alternatively are formed of thermal grease. The thermal grease is typically silicone oil filled with aluminum oxide, zinc oxide, or boron nitride; however, other conductive materials may be used and are contemplated. Some brands of thermal conductive channels 18 use micronized or pulverized silver. Another type of thermal conductive channels 18 are the phase-change materials. The phase change materials are solid at room temperature, but liquefy and behave like grease at operating temperatures. The thermal conductive channels 18 conduct heat to and from portions of the circuitry 14 thereon. The thermal conductive channels 18 couple to solder bumps 17 to interconnect differing chips 13 in the chip stack 10 (e.g., chips 13A and 13B), couple to heat sink 11 through thermal grease 12 or TIM pad 40 of the present invention, that conducts the heat to the side of the chip stack 10.

The electrically conductive channels 16 couple to solder bumps 17 on a bond pad (not shown) on the bottom surface of chip 13 (A-C). The solder bumps 17 are electrically isolated from the chip 13 and one another according to conventional practice. In addition, the electrically conductive channels 16 are preferably electrically insulated from the chip 13 by insulating regions (not shown) which are disposed between the electrically conductive channels 16 and the chip 13. The insulating regions preferably are silicon dioxide (SiO₂); however, other insulating materials may be employed and are contemplated as falling within the scope of the present invention. The insulating regions prevent the signals being transmitted in the electrically conductive channels 16 from disturbing the bias voltage of the chip 13 (which is typically either a ground potential or a Vdd). Of course, in some cases, one of the terminals of the circuitry 14 on the top surface may be held at a substrate potential, in which case, the appropriate electrically conductive channel 16 may be non-insulated and thus be in electrical contact with the chip 13 being held at a similar potential, as may be desired.

As shown, each chip 13 uses electrically conductive channels 16 in a controlled, collapse chip connection (C4) structure (also often called solder bump or flip-chip bonding). The chip stack 10 includes a base chip 13A. Solder bumps 17 are then placed on a bond pad (not shown) for the electrically conductive channels 16 of a second (or top) chip 13A, which is oriented face-down (i.e., flip-chip), aligned and brought into contact with the electrically conductive channels 16. Electrical interconnections between the electrically conductive channels 16 are formed by heating the solder bumps 17 to a reflow temperature, at which point the solder flows. After the solder flows, subsequent cooling results in a fixed, electrically conductive joint to be formed between the electrically conductive channels 16.

The base chip 13A on one side is attached to a heat sink 11 with thermal grease 12. In an alternative embodiment, a thermal interface material incorporating vertically aligned carbon(graphite) nanofibers can be utilized in place of thermal grease 12 as a very effective thermal interface material between a top of base chip 13A and a heat sink 11. Such an arrangement is disclosed in U.S. Patent Application (entitled “A METHOD AND SYSTEM FOR ALIGNMENT OF CARBON NANOFIBERS FOR ENHANCED THERMAL INTERFACE MATERIAL PERFORMANCE”, Ser. No. 12/842,200. Other chips 13B-13D can have C4 connection structures implemented on both the top surface and bottom surface thereof, as illustrated in FIG. 1. In such instances, a second chip 13B may similarly be oriented facedown with respect to the base chip 13A and coupled thereto-using solder bumps 17.

The C4 structure of FIG. 1 overcomes one disadvantage of the connection methodologies. Initially, because the ball-bonding attachment technique is avoided, significantly less stress is placed on the solder bump 17 during connection, which allows circuitry 14 (A-C) to be formed under the solder bump 17. The circuitry 14. (A-C) is formed according to any one of many conventional semiconductor processing techniques. However, the C4 structure of FIG. 1 has one major disadvantage of not being able to dissipate the heat generated by circuitry 14 (A-D). The TIM pad 40 of the present invention, comprises carbon nanotubes (CNTs), carbon nanofibers (CNFs) or graphic nanofibers (GNFs) that are dispersed in a phase change material (PCM) or a silicone grease. The CNTs, CNFs or GNFs are aligned in the position parallel to the surface of the chip 13. This is so that heat may be brought to the edges of the chip stack 10. Once the heat is brought to the edges of the chip stack 10, multiple heat sinks or other type devices may be utilized to more efficiently dissipate that heat of the chip stack 10. In one embodiment, all carbon nanofibers/nanotubes are aligned “east/west” and draw the heat to heat sinks on the east and west sides of the chip stack.

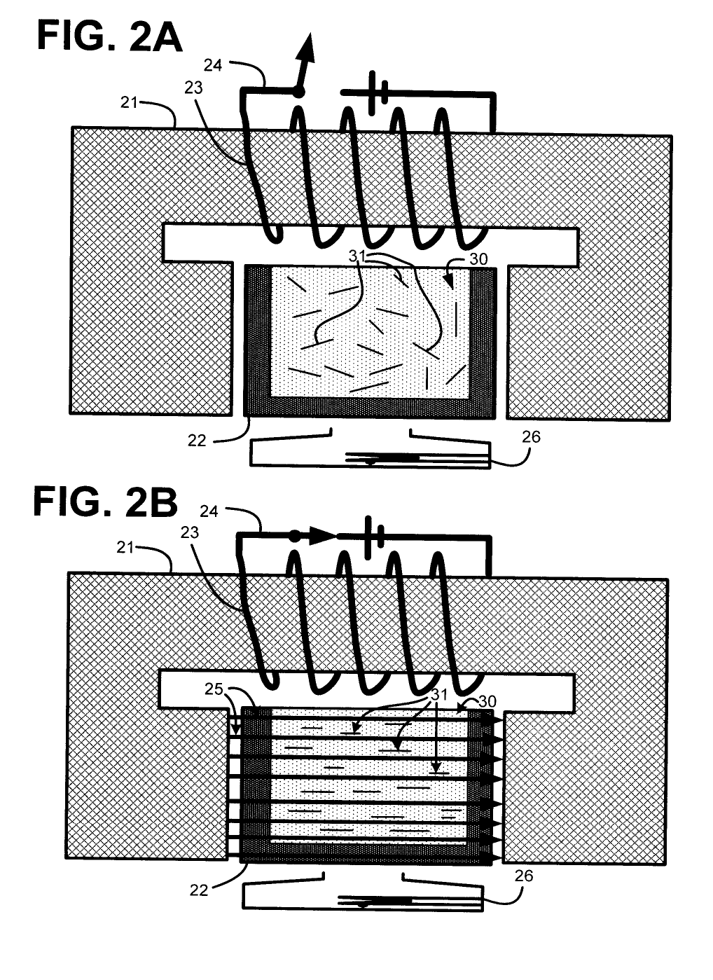

FIG. 2A is a block diagram illustrating an example of the carbon nanofibers 31 containing a magnetic material, randomly dispersed in the thermal interface material 30. The carbon nanofibers 31 are disbursed into the melted thermal interface material 30 using well-established methods. In one embodiment, a high-speed dispersive mixer can be utilized. The carbon nanofibers 31 typically are dispersed essentially homogeneously throughout the bulk of the thermal interface material 30. As shown there is thermal interface material 30 in a crucible 22. The crucible 22 is heated to a temperature so that the thermal interface material 30 melts. The heat is supplied by using well-established heating apparatuses 26. In one embodiment, the thermal interface material 30 is melted at a temperature 10C-20C above the thermal interface material 30 melting temperature. In one embodiments, crucible 22 is surrounded on two sides by electromagnet 21. The magnetic fields are generated in the electromagnet 21 by coils 23 around the electromagnet 21. The coils are connected to switch 24 which allows power to be applied.

FIG. 2B is a block diagram illustrating an example of the reduced viscosity thermal interface material 30 with carbon nanofibers 31 containing a magnetic material, brought to an elevated temperature, leading to an uncross-linking reaction of the thermal interface material 30. The carbon nanofibers 31 containing a magnetic material are then aligned to orient the conductive axis in the desired direction in the thermal interface material 30. The uncross-linking reaction vastly reduces the viscosity of the thermal interface material 30 as compared to typical PCMs. This is illustrated in FIG. 2C.

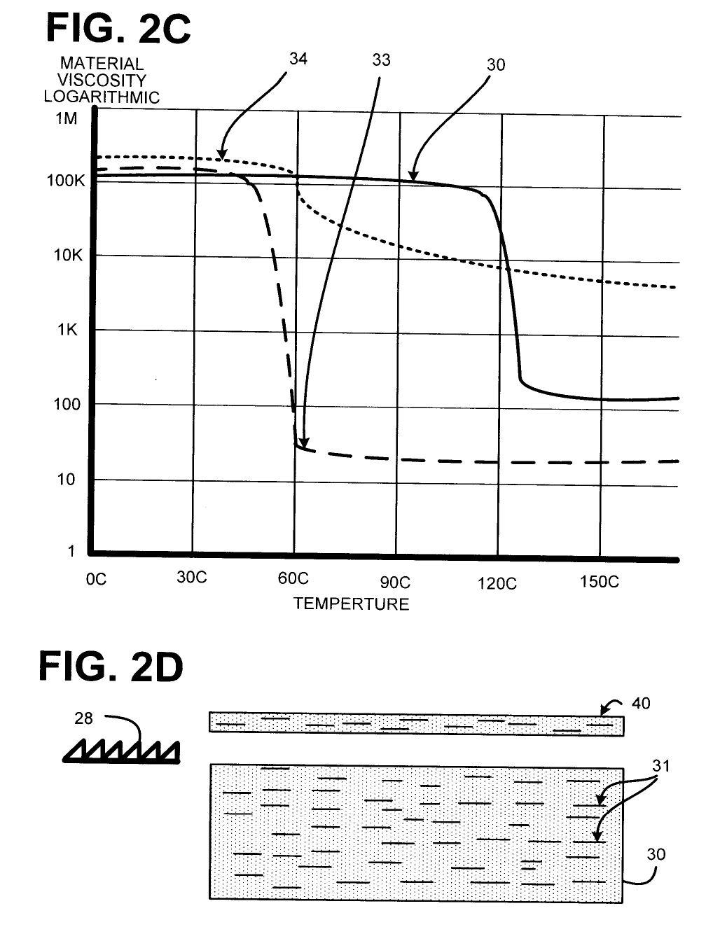

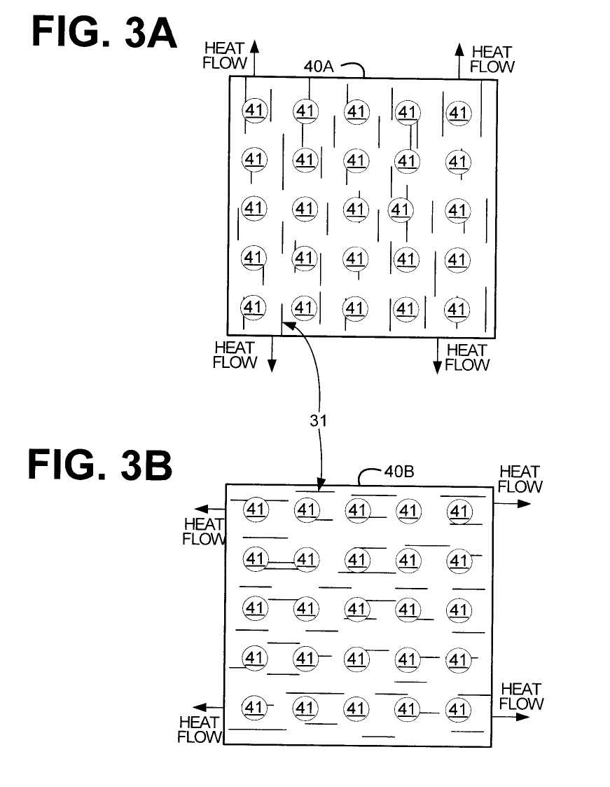

In the preferred embodiment, a magnetic field 25 is applied in a direction parallel to sides of a pad that would be in contact with semiconductor chips or other like electronic devices. The field is strong enough to align the carbon nanofibers/nanotubes containing a magnetic material. The carbon nanofibers 31 can be aligned in the xy plane. In one embodiment, the long axis of the carbon nanofibers 31 are aligned in an orientation parallel to the mating surfaces. This is illustrated in FIGS. 3A and 3B. In another embodiment, the carbon nanofibers 31 are aligned in an orientation perpendicular to the mating surfaces. In still another embodiment, the carbon nanofibers 31 are aligned in an orientation parallel to the mating surfaces, such that two opposite sides of the thermal interface material 30 have carbon nanofibers 31 aligned in one direction parallel with the sides of the thermal interface material 30 and other carbon nanofibers 31 on opposite sides aligned in a second direction perpendicular to the first direction and still parallel with the mating surfaces. This is illustrated in FIG. 4.

The crucible 22 is cooled to approximately room temperature. Once the crucible 22 with the aligned carbon nanofibers 31 in the phase change material has cooled to approximately room temperature, the thermal interface material 30 is removed from the crucible 22. In one embodiment, room temperature is normally within the range of 60 to 80° F., or 15° C. to 27° C. The thermal interface material 30 can be, but is not limited to, paraffins (CₙH₂ₙ₊₂); fatty acids (CH₃(CH₂)₂ₙCOOH); metal salt hydrates (MₙH₂O); and eutectics (which tend to be solutions of salts in water). In still another embodiment the thermal interface material 30 can be silicone-based gels or pastes that are eventually cured into pads.

The TIM pads 40 are then cut to the desired footprint from the thermal interface material 30. This is illustrated in FIG. 2D.

According to the present disclosure, the thermal conductivity at desired locations is increased by TIM pad 40 with aligned carbon nanofibers 31 between the multiple chips 13A-D. By utilizing the TIM pad 40 with aligned carbon nanofibers 31 between multiple chips 13A-D, more heat transfer to the edge of the chip stack 10 can be achieved. The advantage of this solution is that it further reduces chip temperatures through no modification to the chip surface and does not require changes to the manufacturing line or the addition of more components to the system such as liquid coolants and microchannel heat exchangers.

FIG. 2C is a graph illustrating an example of the thermal interface material 30 viscosity reduction by an uncross-linking reaction of the thermal interface material 30 as compared to typical PCMs 33. In the preferred embodiment, heat from well-established heating apparatuses 26 is applied to un-crosslink the least one polymer in the thermal interface material 30. In an alternative embodiment, a solvent or reactive chemical is applied to the thermal interface material 30 to un-crosslink the least one polymer in the thermal interface material. In still another alternative embodiment, a disulfide crosslinked epoxy can be used. The disulfide bond can be reduced using phosphines and then oxidized to reform the disulfide bond. Each example embodiment renders the gel like TIM material into a lower viscosity material allowing for a more facile method of alignment.

Following the uncross-linking reaction, the viscosity of the thermal interface material 30 decreases to approximately 150-400 cSt whereas the viscosity of typical PCMs 33 is at least several orders of magnitude greater than the reactants as crosslinks within the gel build structure in the TIM pads 40. For reference, the viscosity of water @ 20 C is 1.0 cSt or cP because the density is 1.0, and the viscosity of typical non-curing PCMs 33 @ 20 C is generally in the range of 100K-500K cSt. However, typical PCMs 33 will also undergo a dramatic change in viscosity above the melt temperature, however, some PCMs 34 are designed NOT to do so. The reason behind this is to prevent pumping of the liquid PCM 34 as the assembly thermally cycles. By limiting the viscosity of PCMs 34 in the liquid state, this pumping of the liquid PCM 34 can be avoided. However, by doing so, it becomes much more problematic to mix and align the carbon nanofibers 31 in the liquid phase of the liquid PCMs 34. The thermal interface material 30 of the present invention overcomes these limitations by having a very low viscosity fluid to begin with that enables easy CNF/CNT alignment when uncross-linked and then when cross-linked into a gel, it will not pump out.

FIG. 2D is a block diagram illustrating an example of the slicing the thermal interface material into the desired footprint or TIM pad 40. Pads of appropriately sized geometry (length X and width Y) are cut from the slab of thermal interface material 30 using conventional techniques of dicing apparatus 28 known to those skilled in the art. The geometry is dictated by the footprint of the integrated circuit to which the thermal interface material pad 40 will be mated.

FIGS. 3A and 3B are block diagrams illustrating an example of the TIM pad 40 with carbon nanofibers 31 aligned by a magnetic field 25 to orient the conductive axis in perpendicular directions to the TIM pad 40, and having a plurality of areas 41 formed at various locations thereon. Areas 41 provide space for the solder bumps 17 that are formed on electrically conductive channels 16, on the chip 13. The solder bumps 17 rest on electrically conductive channels 16 to connect one chip to another through TIM pad 40 to electrically conductive signals from one chip 13 to another chip 13. In one embodiment, the solder bumps 17 can conduct heat from one chip 13 to another chip 13 and eventually to heat sink 11 or conduct heat laterally from the solder bumps 17 through TIM pad 40 between two chips 13 to the edges of the chip stack 10. In another embodiment, the direction of the carbon nanofibers 31 in TIM pads 40 are alternated among chips so that alternating layers draw heat to heat sinks on the east/west sides of the chip stack and to the north/south side of the chip stack.

As shown, the plurality of solder bumps 17 and areas 41 are circular, however, this is for illustration only and the solder bumps 17 and areas 41 may be of any shape including, but not limited to, triangular, rectangular, square, circular, elliptical, irregular or any four or more sided shape. The size and shape of areas 41 are generally determined by the size and shape of solder bump 17. This is in order to provide a space in the TIM pad 40 for the solder bumps 17.

Also as shown, the solder bumps 17 and areas 41 in one embodiment are laid out in regular patterns, however, this is for illustration only and the solder bumps 17 and areas 41 have the flexibility to be laid out in any desired pattern. This additional level of flexibility allows the circuitry 14 (A-C) to be laid out without regard to the solder bumps 17 and areas 41 locations. This further allows the solder bump 17 locations above the circuitry 14 (A-C) to be located in an optimized fashion, to directly couple with circuitry on another chip 13. In another embodiment, the solder bumps 17 and areas 41 may be formed in a pattern where the electrically conductive channels 16, provide power at the periphery of the chip 13 to aid in cooling the chip 13. Therefore, the solder bumps 17 and areas 41 may be located anywhere on the chip 13A-D as illustrated in FIG. 1, without the need to form such interconnections on peripheral edges of the die.

A TIM pad 40 is used to remove any gaps between thermal transfer surfaces, such as between chips 13 (A-D), microprocessors and heat sinks, in order to increase thermal transfer efficiency. Any gaps normally filled with air, which is a very poor conductor, are replaced by TIM pad 40.

FIGS. 3A and 3B are block diagrams illustrating an example of the thermal interface material pads (TIM) 40A and 40B with carbon nanofibers 31 containing a magnetic material that were aligned by a magnetic field 25 (FIG. 2B) to orient the conductive axis in perpendicular directions to the TIM pad 40A and 40B. In addition, there are a plurality of areas 41 formed at various locations thereon. These areas 41 are for the solder bumps 17 to connect to chips 13 together. In an alternative embodiment, additional TIM pads 40 are in thermal contact with edges of TIM pads 40 hanging out between chips 13, to effectively draw heat to a heat sink 11 on a top of the chip stack 10. In another alternative embodiment, the additional TIM pads 40 are in thermal contact with edges of TIM pads 40 hanging out between chips 13, to effectively draw heat to a heat sink 11 on the sides of the chip stack 10.

FIG. 4 is a block diagram illustrating an example of the thermal interface material (TIM) pad 50 with carbon nanofibers 31 arranged such that two opposite sides of the thermal interface material 30 with carbon nanofibers 31 conduct heat in one direction parallel with the sides of the TIM pad 50 in contact with chip 13 and another two on opposite sides conduct heat in a second direction perpendicular to the first direction and still parallel with the sides of the TIM pad 50 in contact with chip 13. In this alternative embodiment, the uni-directional TIM pad 50 displayed in a top down view illustrated in FIGS. 3A and 3B can be easily sectioned and connected together to conduct heat to all 4 sides of the chip stack as shown. In this alternative embodiment, the pattern areas 51 for the chip solder bumps 17 on TIM pad 50 are generally applied after assembling the TIM pad 50. This is to ensure that the pattern area 51 for the chip solder bumps 17 on chips 13 are properly aligned.

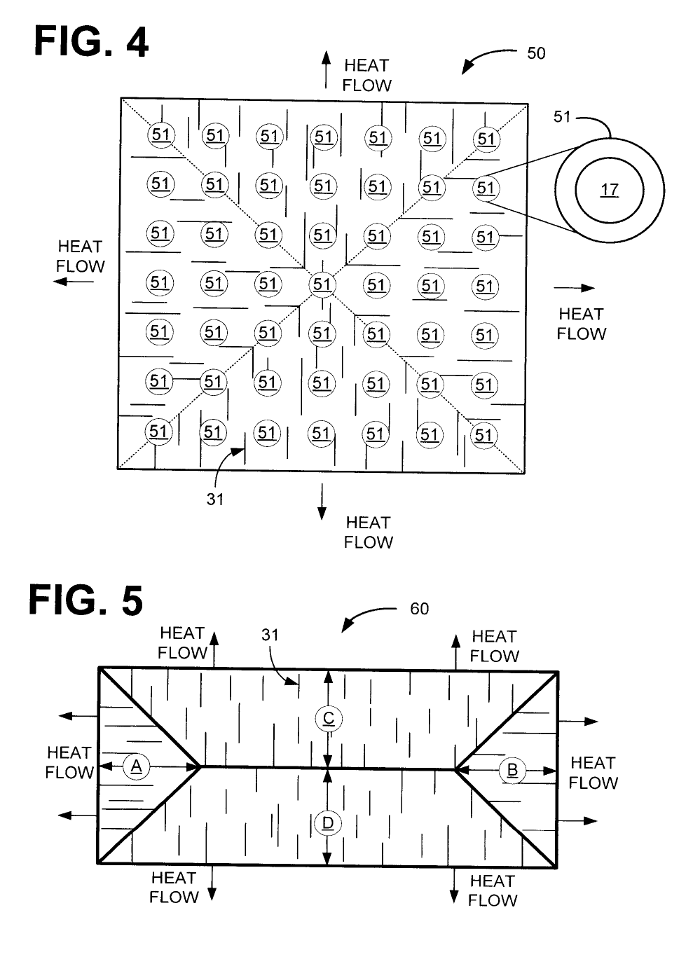

FIG. 5 is a block diagram illustrating another example of the thermal interface material (TIM) pad 60 with carbon nanofibers 31 arranged such that two opposite sides of the thermal interface material 30 with carbon nanofibers 31 conduct heat one direction parallel with the sides of the TIM pad 60 in contact with chip 13 and another two on opposite sides conduct heat in a second direction perpendicular to the first direction and still parallel with the sides of the TIM pad 40 in contact with chip 13. In this alternative embodiment, the uni-directional TIM pad 40 displayed in a top down view illustrated in FIGS. 3A and 3B can be easily sectioned and connected together to conduct heat to all 4 sides of the chip stack as shown, so that the carbon nanofibers 31 conduct heat to the closest edge of the TIM pad 60. In this alternative embodiment, the TIM pad 60 is in a rectangular shape where A=B=C=D no matter what the W/L ratio of the rectangle. In this alternative embodiment, a chip stack 10 of memory chips is covered. The pattern areas for the chip solder bumps 17 on TIM pad 60 are generally applied after assembling the TIM pad 60. This is to ensure that the pattern area for the chip solder bumps 17 on chips 13 are properly aligned.

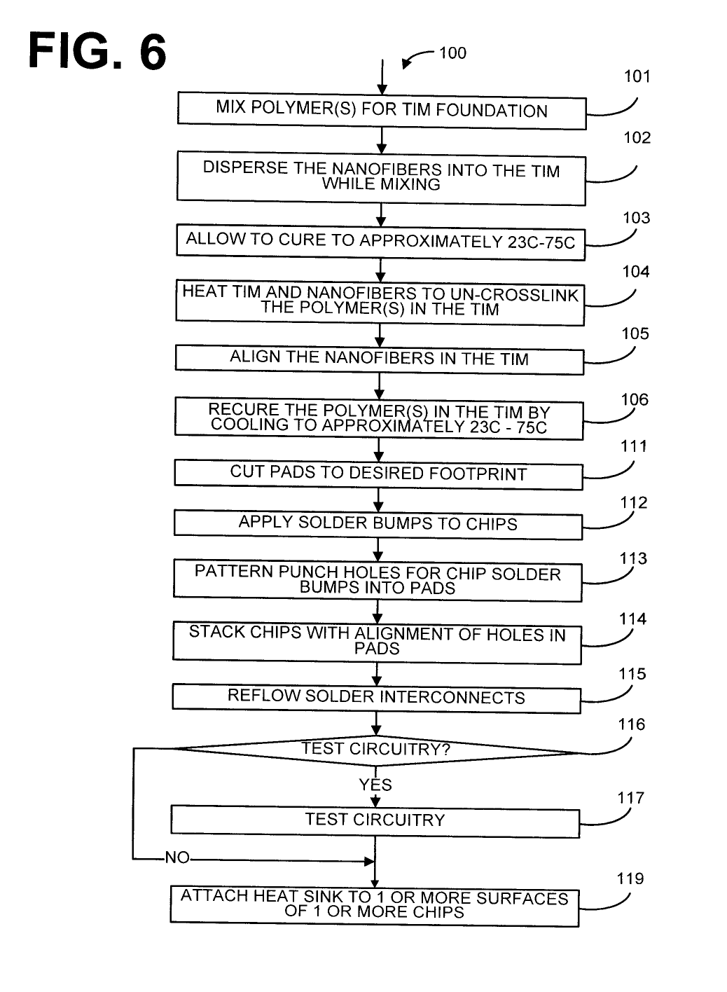

FIG. 6 is a flow chart illustrating an example of a method of forming a chip stack 10 utilizing the TIM pad 40 with carbon nanofibers 31 aligned by a magnetic field 25 to orient the conductive axis in the desired direction of the present invention. There are a couple approaches to forming the individual chips 13, and subsequent assembly, so the following is just one method of constructing silicon devices in a multilayer chip stack 10 utilizing the thermal interface material pad 40 with aligned carbon nanofibers 31.

At step 101, at least one thermosetting polymer is added to create the thermal interface material 30 foundation. In one embodiment, the thermal interface material 30 is prepared according to the following procedure. To a 25 mL round bottom flask, aminopropylmethyl-Dimethylsiloxane copolymer (5 g, 0.002 moles APTES) (This polymer is commercially available from Gelest Inc.) is added along with anhydrous tetrahydrofuran (THF), a solvent (15 mL) and a stir bar. To this solution, furfuryl isocyante (0.262 g, 0.002 moles) is added drop wise. The reaction is stirred for 24 hrs at 50 C. THF is removed via distillation to yield the desired furfuryl polydimethylsiloxane (PDMS).

In an alternative embodiment, polymer 2 was prepared according to the following procedure. To a 100 mL RBF, a furan protected maleic anhydride (0.5 g, 0.002 moles) is dissolved in 30 mL of benzene followed by the addition of a magnetic stir bar. To this solution, aminopropylmethyl-dimethylsiloxane copolymer (5 g, 0.002 moles APTES) (This polymer is commercially available from Gelest Inc.) is added drop wise along with benzene (20 mL). This reaction is magnetic mixed for 2 hrs at 80 C. Then ZnCl₂ (0.27 g, 0.002 moles) is added and magnetically stirred for 30 min. Then a solution of hexamethyldisilazane (HMDS) (0.48 g, 0.003 moles) and benzene (2.0 mL) is added drop wise and reaction was brought to reflux and mixed for 1 h. The solution is filtered and washed with 0.5 N HCl to work up. The organic layer is dried with magnesium sulfate and the volatiles removed by distillation.

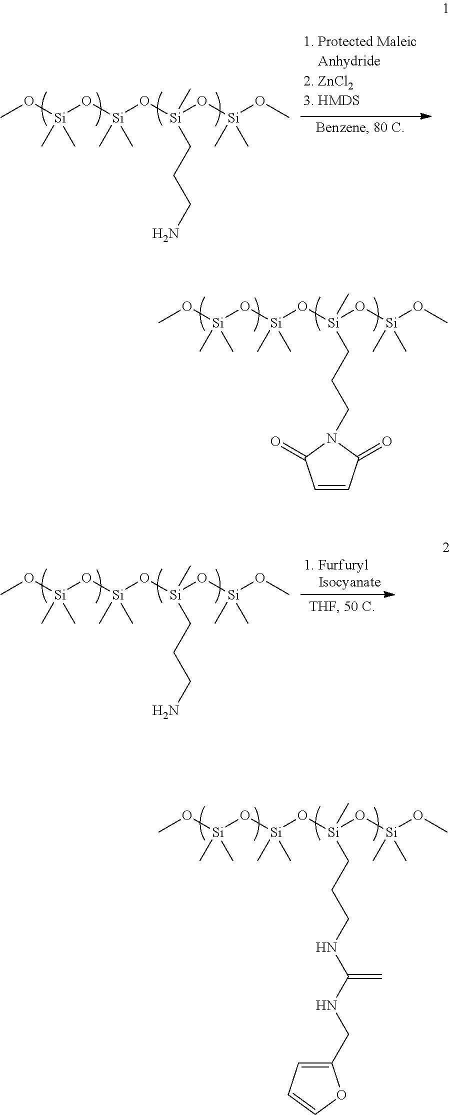

To prepare the TIM formulation, polymer 1 and polymer 2 are to be used at equal weight percents. While mixing polymer 1 and 2 together, the carbon fiber like structures can be added and mixed. Once mixed in, it can be applied and allowed to cure from room temperature to 70 C. When ready to align, the temperature is brought to approximately 110 C, at which point the polymer will under go a retro diels alder reaction and un-crosslink the polymer, thus reducing the viscosity significantly and allowing for facile alignment via an external field. This will allow for optimal alignment of the carbon nanofibers 31 like structures. Below is an example to demonstrate the retro-diels alder reaction.

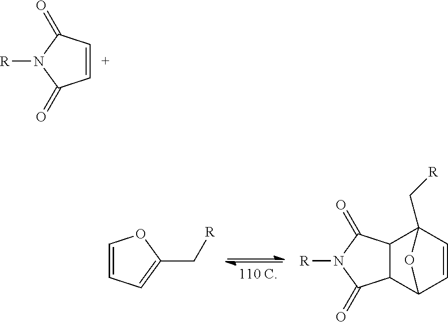

R=Where function ality is bonded to polymer

Below is another example of a TIM formulation, which would allow for rapid viscosity changes to facilitate alignment of the carbon nanofibers 31 like structures.

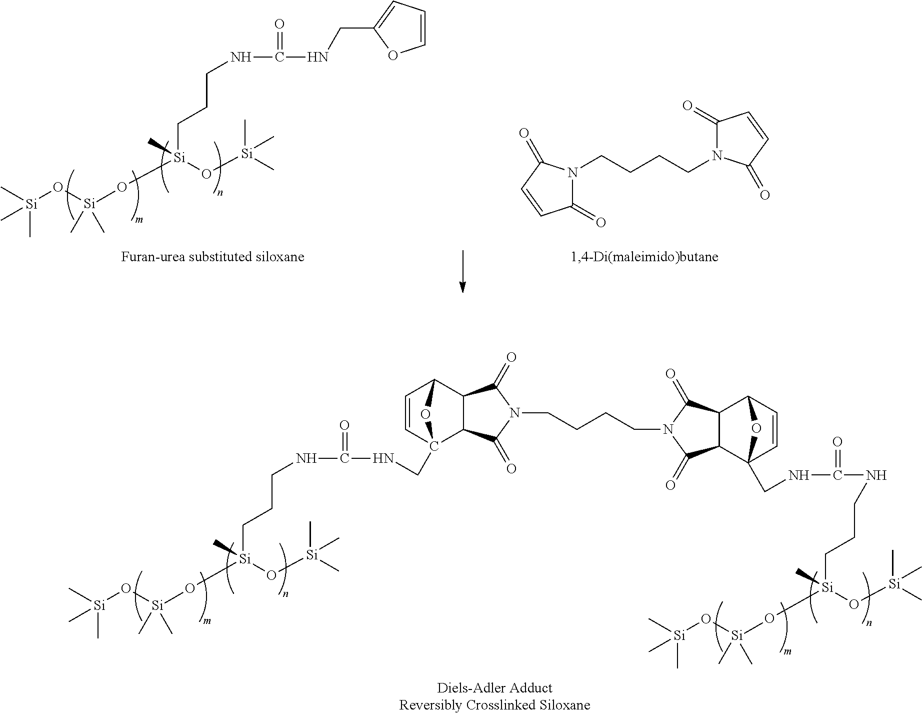

Another suitable matrix based on reversible isocyanate reaction with phenol functionality is as follows where the R group can be a wide number of functional groups which will change the reversibility temperature as long as one R group is bound to a polymer to create a TIM formulation:

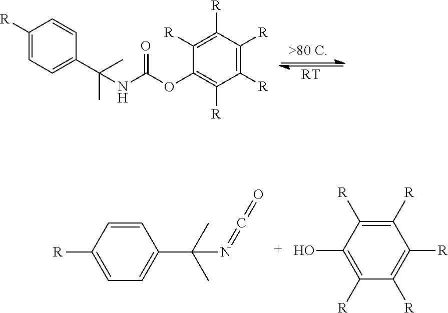

At step 102, the carbon nanofibers 31 are disbursed into the melt using well-established methods. In one embodiment, a high-speed dispersive mixer can be utilized. The amount of carbon nanofibers 31 in the thermal interface material 30 of the present invention will typically be in the range of 4 to 10 weight percent based on the amount of thermal interface material 30, preferably ˜5 weight percent. The carbon nanofibers 31 typically are dispersed essentially homogeneously throughout the bulk of the thermal interface material 30. In an alternative embodiment, carbon nanotubes may be substituted for the carbon nanofibers 31.

At step 103, the thermal interface material 30 with the carbon nanofibers 31 is cooled to approximately 23° C.-75° C. in order to cure. At step 104, the thermal interface material 30 with the carbon nanofibers 31 is heated to a temperature to un-crosslink the polymers in the thermal interface material 30. In the preferred environment, the temperature of the thermal interface material is heated to and maintained at approximately 110° C.-125° C.

At step 105, a magnetic field 25 (FIG. 2B) of sufficient intensity is applied to the thermal interface material 30 containing the carbon nanofibers 31, in order to align the carbon nanofibers 31. In one embodiment, the long axis of the carbon nanofibers 31 are aligned along the conductive axis of the graphite fibers. In another embodiment, the carbon nanofibers 31 are aligned in an orientation perpendicular to the mating surfaces. In still another embodiment, the magnetic field is normally within the range of 500-100,000 Gauss or 0.05-10 Tesla.

At step 106, the thermal interface material 30 containing the carbon nanofibers 31 is cooled to approximately 23° C.-75° C. in order to recure the polymers in the thermal interface material. At step 111, the TIM pads 40 are cut to the desired footprint. TIM pads 40 of appropriately sized geometry (length X, width Y and thickness Z) are cut from the slab of thermal interface material 30 using conventional techniques known to those skilled in the art. The geometry of TIM pad 40 is dictated by the footprint of the integrated circuit to which the TIM pads 40 will be mated.

At step 112, solder bumps 17 are then formed on the on the bottom surface of the chip 13. These solder bumps 17 are generally in alignment with the electrically conductive channels 16 on chip 13 in order to conduct electrical signals. In an alternative embodiment, thermal conductive channels 18 may conduct heat instead of electronic signals and use a solder bump 17 with thermal conductive ability. In one embodiment, a homogenous process could be used to create solders bump 17 for both electrically conductive channels 16 and any thermal conductive channels 18.

At step 113, areas 41 are placed within the pads 42 corresponding with solder bumps 17 on chips 13. This will allow these solder bumps on chip 13 to extend through TIM pads 40 in order to mechanically and electrically connect another chip 13. At step 114, the chips 13 in the chip stack 10 are assembled with the TIM pads 40 in between two adjacent chips 13.

At step 115, the chip stack 10 is heated to a reflow temperature, at which point the solder in the solder bumps 17 flows. Subsequent cooling results in a fixed, electrically conductive joint to be formed between the electrically conductive channels 16. An example of this is to have the bottom surface of a first chip 13A coupled to a top surface of a second chip 13B with a TIM pad 40A (FIG. 1) in between.

At step 116, it is determined if the circuitry on chips 13 in chip stack 10 are to be tested. If it is determined in step 116 that testing the circuitry in the chip stack 10 is not to be performed, then the method 100 skips to step 119. However, if it is determined at step 114 that the circuitry on chips 13 in chip stack 10 are to be tested, then the circuitry is tested for electrical performance, at step 117.

At step 119, the method 100 attaches a heat sink 11 to one or more surfaces of one or more chips 13.

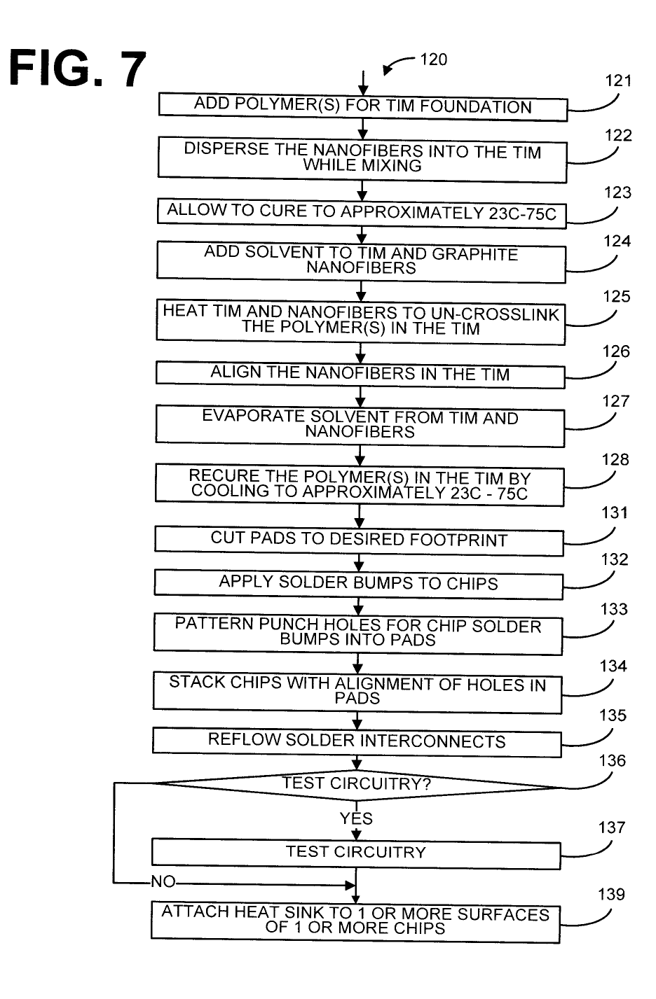

FIG. 7 is a flow chart illustrating an example of a method of constructing silicon devices in a multilayer chip stack 10 utilizing the thermal interface material 30 with carbon nanofibers 31 heated and aligned by using a solvent to orient the conductive axis of the carbon nanofibers 31 in the desired direction of the present invention.

At step 121, at least one thermosetting polymer is added to create the thermal interface material 30 foundation. In one embodiment, the thermal interface material 30 is prepared according to the following procedure. To a 25 mL round bottom flask, aminopropylmethyl-Dimethylsiloxane copolymer (5 g, 0.002 moles APTES) (This polymer is commercially available from Gelest Inc.) is added along with anhydrous THF (15 mL) and a stir bar. To this solution, furfuryl isocyante (0.262 g, 0.002 moles) is added drop wise. The reaction is stirred for 24 hrs at 50 C. THF is removed via distillation to yield the desired furfuryl PDMS.

At step 122, the carbon nanofibers 31 are disbursed into the melt using well-established methods. In one embodiment, a high-speed dispersive mixer can be utilized. The amount of carbon nanofibers 31 in the thermal interface material 30 of the present invention will typically be in the range of 4 to 10 weight percent based on the amount of thermal interface material 30, preferably ˜5 weight percent. The carbon nanofibers 31 typically are dispersed essentially homogeneously throughout the bulk of the thermal interface material 30. In an alternative embodiment, carbon nanotubes may be substituted for the carbon nanofibers 31.

At step 123, the thermal interface material 30 with the carbon nanofibers 31 is cooled to approximately 23° C.-75° C. in order to cure. At step 124, a solvent is added to the thermal interface material 30 with the carbon nanofibers 31 to assist in un-crosslinking the polymers in the thermal interface material 30. In the preferred environment, the solvent is THF or other suitable solvent known to those skilled in the art. At step 125, the thermal interface material 30 with the carbon nanofibers 31 is heated to a temperature to un-crosslink the polymers in the thermal interface material 30. In the preferred environment, the temperature of the thermal interface material is heated to and maintained at approximately 110° C.-125° C.

At step 126, a magnetic field 25 (FIG. 2B) of sufficient intensity is applied to the thermal interface material 30 containing the carbon nanofibers 31, in order to align the carbon nanofibers 31. In one embodiment, the long axis of the carbon nanofibers 31 are aligned along the conductive axis of the graphite fibers. In another embodiment, the carbon nanofibers 31 are aligned in an orientation perpendicular to the mating surfaces. In still another embodiment, the magnetic field is normally within the range of 500-100,000 Gauss or 0.05-10 Tesla. At step 127, the solvent within the thermal interface material 30 containing the carbon nanofibers 31 is evaporated off. In an alternative embodiment, a vacuum stripping method can be used, where the material is simply subjected to a vacuum. At step 128, the thermal interface material 30 with the carbon nanofibers 31 is cooled to approximately 23° C.-75° C. in order to recure the polymers in the thermal interface material.

At step 131, the TIM pads 40 are cut to the desired footprint. TIM pads 40 of appropriately sized geometry (length X, width Y and thickness Z) are cut from the slab of thermal interface material 30 using conventional techniques known to those skilled in the art. The geometry of TIM pad 40 is dictated by the footprint of the integrated circuit to which the TIM pads 40 will be mated.

At step 132, solder bumps 17 are then formed on the bottom surface of the chip 13. These solder bumps 17 are generally in alignment with the electrically conductive channels 16 on chip 13 in order to conduct electrical signals. In an alternative embodiment, thermal conductive channels 18 may conduct heat instead of electronic signals and use a solder bump 17 with thermal conductive ability. In one embodiment, a homogenous process could be used to create solder bumps 17 for both electrically conductive channels 16 and any thermal conductive channels 18.

At step 133, areas 41 are placed within the pads 42 corresponding with solder bumps 17 on chips 13. This will allow these solder bumps on chip 13 to extend through TIM pads 40 in order to mechanically and electrically connect another chip 13. At step 134, the chips 13 in the chip stack 10 are assembled with the TIM pads 40 in between two adjacent chips 13.

At step 135, the chip stack 10 is heated to a reflow temperature, at which point the solder in the solder bumps 17 flows. Subsequent cooling results in a fixed, electrically conductive joint to be formed between the electrically conductive channels 16. An example of this is to have the bottom surface of a first chip 13A coupled to a top surface of a second chip 13B with a TIM pad 40A (FIG. 1) in between.

At step 136, it is determined if the circuitry on chips 13 in chip stack 10 are to be tested. If it is determined in step 136 that testing the circuitry in the chip stack 10 is not to be performed, then the method 120 skips to step 139. However, if it is determined at step 136 that the circuitry on chips 13 in chip stack 10 are to be tested, then the circuitry is tested for electrical performance, at step 137.

At step 139, the method 120 attaches a heat sink 11 to one or more surfaces of one or more chips 13.

The terminology used herein is for describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The flowchart and block diagrams in the Figures illustrate the functionality, and operation of possible implementations of systems and methods according to various embodiments of the present invention. In this regard, each block in the flowchart or block diagrams may represent a module, segment, or task to be performed, which comprises one or more executable steps for implementing the specified function(s). It should also be noted that, in some alternative implementations, the functions noted in the block may occur out of the order noted in the Figures. For example, two blocks shown in succession may in fact be performed substantially concurrently or the blocks may sometimes be executed in the reverse order, depending upon the functionality involved.

It should be emphasized that the above-described embodiments of the present invention, particularly any “preferred” embodiments, are merely possible examples of implementations set forth for a clear understanding of the principles of the invention. Many variations and modifications may be made to the above-described embodiment(s) of the invention without departing substantially from the spirit and principles of the invention. All such modifications and variations are intended to be included herein within the scope of this disclosure and the present invention and protected by the following claims.

1-14. (canceled)

15. A chip stack of semiconductor chips with enhanced cooling comprising:
a first chip with circuitry on a first side;
a second chip electrically and mechanically coupled to the first chip by a grid of connectors;
a thermal interface material pad between the first chip and the second chip, wherein the thermal interface material pad further comprises:
a plurality of nanofibers containing a magnetic material, aligned parallel to mating surfaces of the first chip and the second chip; and
at least one thermosetting polymer that when heated to at least 110° C., the at least one thermosetting polymer will un-crosslink and reduce viscosity of the thermal interface material to allow for optimal alignment of the plurality of nanofibers containing the magnetic material.

16. The chip stack of claim 15, wherein the plurality of nanofibers are aligned parallel to mating surfaces of the thermal interface material.

17. The chip stack of claim 15, wherein the plurality of nanofibers are aligned perpendicular to mating surfaces of the thermal interface material.

18. The chip stack of claim 15, wherein the plurality of nanofibers containing the magnetic material are a plurality of nanotubes containing the magnetic material.

19. The chip stack of claim 15, wherein the plurality of nanofibers in the thermal interface material pad are arranged so that both ends of each of the plurality of nanofibers are perpendicular to an edge of the thermal interface material pad closest to each of the plurality of nanofibers.

20. An apparatus comprising:
a first object;
a second object;
a thermal interface material having a thickness between a first surface of the thermal interface material and a second surface of the thermal interface material, the thermal interface material further comprising:
a plurality of nanofibers containing a magnetic material, aligned parallel to the first surface and the second surface; and
at least one thermosetting polymer that when heated to at least 110° C., the at least one thermosetting polymer will un-crosslink and reduce viscosity of the thermal interface material to allow for optimal alignment of the plurality of nanofibers containing the magnetic material.

21. The apparatus of claim 20, wherein the plurality of nanofibers are aligned parallel to mating surfaces of the thermal interface material.

22. The apparatus of claim 20, wherein the plurality of nanofibers are aligned perpendicular to mating surfaces of the thermal interface material.

23. The apparatus of claim 20, wherein the plurality of nanofibers in the thermal interface material are arranged so that both ends of each of the plurality of nanofibers are perpendicular to an edge of the thermal interface material closest to each of the plurality of nanofibers.

24. The apparatus of claim 20, wherein the plurality of nanofibers are a plurality of nanotubes.

25. The apparatus of claim 20, wherein the first object is a heat generating object and the second object is a heat dissipating object.
